(19) United States
(12) Patent Application Publication
(10) Pub. No.: US 2024/0387590 A1
(43) Pub. Date: Nov. 21, 2024

(54) IMAGE SENSOR AND MANUFACTURING METHOD THEREOF

(71) Applicant: Samsung Electronics Co., Ltd., Suwon-si (KR)

(72) Inventors: Jinpyo Kim, Suwon-si (KR); Byungjun Park, Suwon-si (KR); Jimin Jeun, Suwon-si (KR); Hakyu Choi, Suwon-si (KR)

(21) Appl. No.: 18/515,334

(22) Filed: Nov. 21, 2023

(30) Foreign Application Priority Data
May 16, 2023 (KR) 10-2023-0063021

(51) Int. Cl. H01L 27/146

(52) U.S. Cl. CPC H01L 27/14636; H01L 27/14689

(57) ABSTRACT

An image sensor includes a substrate structure including a sensor array region and a pad region adjacent to the sensor array region. The substrate structure includes a first substrate structure and a second substrate structure. The first substrate structure is on the second substrate structure. The image sensor includes a penetrating structure including a first conductive material layer and a second conductive material layer in at least a portion of the first substrate structure. The second conductive material layer is electrically connected to the first conductive material layer and extends into the first substrate structure.

### CROSS-REFERENCE TO RELATED APPLICATION

This application claims priority to and the benefit of Korean Patent Application No. 10-2023-0063021 filed in the Korean Intellectual Property Office on May 16, 2023, the entire contents of which are incorporated herein by reference.

### TECHNICAL FIELD

The present disclosure relates to an image sensor. More particularly, the present disclosure relates to an image sensor and a manufacturing method thereof.

### BACKGROUND

An image sensor converts optical images into electric signals. The image sensor may, for example, be classified as a charge coupled device (CCD) image sensor or a complementary metal oxide semiconductor (CMOS) image sensor. The CMOS image sensor may be referred to hereinafter as a CIS.

The CIS may convert light energy into electrical energy and may read image information. As an example, the CIS may convert analog video signals input through a lens into electrical video signals, and may transmit CMOS digital signals, which is different from the CCD image sensor for transmitting charges.

As a specific example, the CIS includes pixels arranged in a two-dimensional manner and that use transistors, and signal charges generated by a photodiode may be converted into voltages in the respective pixels and may be output. The CIS may be manufactured by the commercial CMOS methods.

When the CIS is manufactured, an ALO capping on tungsten (W) may be deposited in the CIS pad region, and when a temperature humidity bias (THB) reliability estimation is performed, tungsten is oxidized and erupted, and a structural integrity of an exterior may decrease. Further, a step is generated between silicon and tungsten in the CIS pad, and a folding profile may be formed on a film on tungsten in the generated region, thereby inhibiting the performance of the CIS.

### SUMMARY

The present disclosure providing an image sensor that reduces step defects between a pad region and tungsten when manufacturing a CIS.

The present disclosure also provides a method for manufacturing an image sensor.

An embodiment of the present disclosure provides an image sensor including: a substrate structure that includes a sensor array region and a pad region adjacent to the sensor array region, where the substrate structure includes a first substrate structure and a second substrate structure, and where the first substrate structure is on the second substrate structure; and a penetrating structure including a first conductive material layer and a second conductive material layer in at least a portion of the first substrate structure, where the second conductive material layer is on and electrically connected to the first conductive material layer, and where the second conductive material layer extends into the first substrate structure.

The image sensor may include a first protective layer on a surface insulation layer and a connection structure on the first protective layer, and the second conductive material layer may be between the first protective layer and the connection structure. The first substrate structure may include an upper substrate and a lower substrate below or on the upper substrate, and the penetrating structure may extend into the upper substrate.

The penetrating structure may extend into the upper substrate and the lower substrate. The penetrating structure may be connected to a metal line pattern on an uppermost portion of the second substrate structure.

The penetrating structure may extend into at least a portion of the upper substrate. The image sensor may include a wire structure on the lower substrate, where the wire structure electrically connects the first substrate structure and the second substrate structure. The penetrating structure may extend in a thickness direction of the first conductive material layer.

A plurality of penetrating structures may extend in a thickness direction of the first conductive material layer. A ratio of a length of a long axis of the pad region to a length of a short axis may be 0.8 to 1.7. A length of the long axis of the pad region may be 90 to 150 μm. The first substrate structure may include a lower substrate and an upper substrate on the lower substrate, and at least a portion of the first conductive material layer is in the upper substrate. The second conductive material layer includes at least one of tungsten (W), copper (Cu), aluminum (Al), gold (Au), silver (Ag), and alloys thereof.

Another embodiment of the present disclosure provides an image sensor including: a substrate structure that includes a sensor array region and a pad region adjacent to the sensor array region, where the substrate structure includes a first substrate structure and a second substrate structure, where the first substrate structure is on the second substrate structure, where the first substrate structure includes an upper substrate and a lower substrate, and where the second substrate structure includes second wire patterns; and a penetrating structure that extends into the first substrate structure, where the penetrating structure includes a first conductive material layer in at least a portion of the first substrate structure in the pad region, where the penetrating structure includes a second conductive material layer that is on the first conductive material layer and extends into the upper substrate and the lower substrate, and where the penetrating structure includes a connection structure that is electrically connected to the second wire patterns.

The second conductive material layer may at least partially surround a sidewall of the first conductive material layer. The image sensor may include a first protective layer on a surface insulation layer, the connection structure is on the first protective layer, and the second conductive material layer may be between the first protective layer and the connection structure. A ratio of a length of a long axis of the pad region to a length of a short axis may be 0.8 to 1.7 in a plan view.

Another embodiment of the present disclosure provides a substrate structure that includes a first substrate structure and a second substrate structure on the first substrate structure; and a penetrating structure including a first conductive material layer and a second conductive material layer on and electrically connected to the first conductive material layer, where first substrate structure includes a lower substrate and an upper substrate on the lower substrate, and where the second conductive material layer extends into at least one of the lower substrate and the upper substrate and at least partially surrounds a sidewall of the first conductive material layer.

The second substrate structure may further include wire patterns, and the penetrating structure may further include a connection structure that is electrically connected to the wire patterns. The image sensor may include a first protective layer on a surface insulation layer, the connection structure is on the first protective layer, and the second conductive material layer may be between the first protective layer and the connection structure.

Another embodiment of the present disclosure provides a method for manufacturing an image sensor including: combining a first substrate structure and a second substrate structure including a lower substrate and an upper substrate; forming a pad trench in the first substrate structure; forming at least one penetration hole below the pad trench to penetrate the first substrate structure; forming a conductive material layer in the penetration hole by using a first conductive material; and forming a conductive pad on the conductive material layer by using a second conductive material. The conductive material layer may contact an entire bottom surface of the conductive pad. The method may further include applying an adhesive material before the forming of a conductive material layer in the penetration hole by using a first conductive material.

The image sensor according to an embodiment of the present disclosure vertically disposes the pad and the tungsten to minimize exposure of the tungsten and minimize the step of the pad region, and thereby reduces or inhibits the defects of the image sensor and simplifies the structure of the pad region.

The method for manufacturing an image sensor according to an embodiment of the present disclosure provides the image sensor with the above-noted advantages.

### BRIEF DESCRIPTION OF THE DRAWINGS

FIG. 1 shows a block diagram of an image sensor according to an embodiment of the present disclosure.

FIG. 2 shows a circuit diagram of a unit pixel region of a pixel array according to an embodiment of the present disclosure.

FIG. 3 shows a conceptual layout of an image sensor according to an embodiment of the present disclosure.

FIG. 4 shows a conceptual layout of an image sensor according to another embodiment of the present disclosure.

FIG. 5 shows a layout diagram of an image sensor according to an embodiment of the present disclosure.

FIG. 6 shows a cross-sectional view of an image sensor with respect to a line AA′ of FIG. 5 according to an embodiment of the present disclosure.

FIGS. 7A, 7B, 7C, 7D, and 7E show an enlarged region P1 of FIG. 6.

FIGS. 8A, 8B, 8C, 8D, and 8E show top plan views of an embodiment of FIG. 7A to FIG. 7E shown in a region AB of FIG. 6.

FIG. 9 shows a cross-sectional view of an image sensor with respect to a line AA′ of FIG. 5 according to another embodiment of the present disclosure.

FIGS. 10A, 10B, and 10C show an enlarged region P3 of FIG. 9.

FIGS. 11A, 11B, 11C, 11D, 11E, 11F, and 11G show a method for manufacturing an image sensor according to an embodiment of the present disclosure.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Parts that are irrelevant to the description will be omitted to clearly describe the present disclosure, and the same elements will be designated by the same reference numerals throughout the specification.

The size and thickness of each configuration shown in the drawings are arbitrarily shown for better understanding and ease of description, but the present disclosure is not limited thereto. In the drawings, the thickness of layers, films, panels, regions, etc., are enlarged for clarity. The thicknesses of some layers and areas are exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

Hereinafter, several embodiments of the present disclosure will be described in detail so that those skilled in the art to which the present disclosure pertains may easily practice the present disclosure. However, the present disclosure may be implemented in various different forms and is not limited to embodiments provided herein.

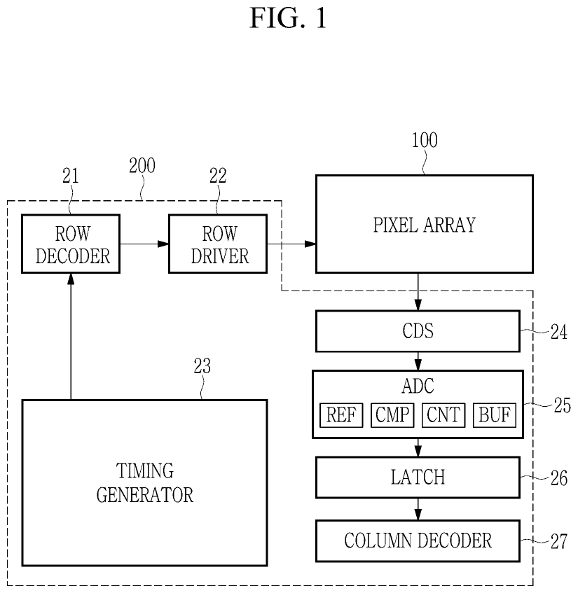

FIG. 1 shows a block diagram of an image sensor according to an embodiment of the present disclosure.

Referring to FIG. 1, a semiconductor chip including a pixel array 100 and a semiconductor chip including a logic circuit 200 may be stacked and disposed.

The pixel array 100 may convert incident light into electrical signals. The pixel array 100 may include unit pixel regions disposed in a matrix format in a row direction and a column direction. As an example, the pixel array 100 may be driven by control of the logic circuit 200. As a specific example, the logic circuit 200 may control transistors included in the pixel array 100.

The logic circuit 200 may receive data from the pixel array 100 and may generate image frames. For example, the logic circuit 200 may perform various methods, such as a global shutter method for simultaneously sensing the unit pixel regions, a flutter shutter method for adjusting an exposure time for simultaneously sensing the entire unit pixel regions, a rolling shutter method for controlling the unit pixel regions for respective rows, or a coded rolling shutter method.

The logic circuit 200 may include a row decoder 21, a row driver 22, a timing generator 23, a correlated double sampler CDS 24, an analog to digital converter ADC 25, a latch portion LATCH 26, and a column decoder 27.

The row driver 22 may control the row unit pixel array 100 according to the control of the timing generator 23. The row driver 22 may select at least one of the rows of the pixel array 100 according to a row address. The row driver 22 may decode the row address and may be connected to a selection transistor, a reset transistor, and a source follower transistor. The pixel array 100 may be driven by driving signals received from the row driver 22, such as a pixel selection signal, a reset signal, and a charge transmitting signal.

The timing generator 23 provides a timing signal and a control signal to the row decoder 21 and the column decoder 28. The row driver 22 provides driving signals for driving unit pixels to the pixel array according to a result decoded by the row decoder 21. When the unit pixels PX are arranged in a matrix format, the driving signals are provided for respective rows of the matrix.

The correlated double sampler 24 receives output signals from the pixel array 100 and samples and holds the same. As an example, a difference level between a noise level and a signal level is output by double sampling a signal level caused by a specific noise level and an output signal.

The analog to digital converter 25 converts an analog signal that corresponds to the difference level into a digital signal and outputs the digital signal. As an example, the analog to digital converter 25 may convert analog signals received from the pixel array 100 through column lines into digital signals. The number of the analog to digital converters 25 may be determined by the number of the unit pixel regions disposed in one row and the number of column lines. The number of analog to digital converters 25 may be at least one as a nonlimiting example.

The analog to digital converter 25 may include a reference signal generator REF, a comparator CMP, a counter CNT, and a buffer BUF. The reference signal generator REF may generate a lamp signal having a specific slope, and may provide the lamp signal as a reference signal of the comparator. The comparator CMP may compare the analog signal and the lamp signal of the reference signal generator REF and may output comparison signals having respective transition times according to valid signal components. The counter CNT may perform a counting operation to generate counting signals, and may provide them to the buffer BUF. The buffer BUF may include circuits of the latch portion 26 connected to the column lines, may latch the counting signal output by the counter CNT for respective columns in response to the transition of the comparison signal, and may output the latched counting signal as data.

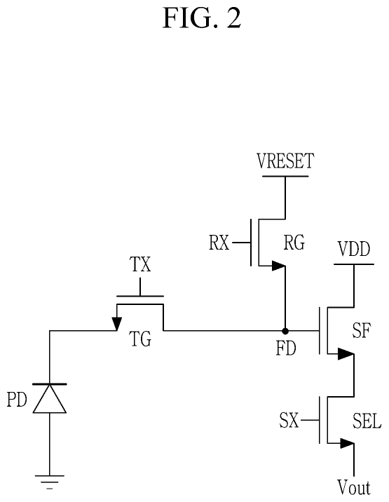

FIG. 2 shows a circuit diagram of a unit pixel region of a pixel array according to an embodiment of the present disclosure.

Referring to FIG. 2, the pixel array may include a photoelectric conversion layer PD, a transmission transistor TX, a floating diffusion region FD, and a reset transistor RX.

The photoelectric conversion layer PD may generate charges proportional to an amount of light received from an external environment. The photoelectric conversion layer PD may be a photodiode including an N-type impurity region and a P-type impurity region. The photoelectric conversion layer PD may be coupled to the transmission transistor TX for transmitting the generated and stored charges to the floating diffusion region FD. The floating diffusion region FD may have parasitic capacitance for converting charges to voltages and may stack and store charges.

A first end of the transmission transistor TX may be connected to the photoelectric conversion layer PD, and a second end of the transmission transistor TX may be connected to the floating diffusion region FD. The transmission transistor TX may be formed with a transistor driven by transmission signals that has a predetermined bias. The transmission signal may be applied through a transmission gate TG. As an example, the transmission transistor TX may transmit the charges generated by the photoelectric conversion layers to the floating diffusion region FD according to the transmission signals.

The source follower transistor SX may amplify a change of electrical potential of the floating diffusion region FD having received the charges from the photoelectric conversion layer PD and may output the amplified change to an output line Vout. A predetermined electrical potential, for example, a power source voltage VDD, provided to a drain of the source follower transistor SX may be transmitted to a drain region of the selection transistor. A source follower gate SF of the source follower transistor SX may be connected to the floating diffusion region FD.

The selection transistor may select the unit pixel region to be read per row unit. The selection transistor may be formed with a transistor driven by a predetermined bias, for example, a selection line for applying a row selection signal. The row selection signal may be applied through the selection gate SEL.

The reset transistor RX may periodically reset the floating diffusion region FD. The reset transistor RX may be formed with a transistor driven by a predetermined bias, for example, a reset line for applying a reset signal. The reset signal may be applied through the reset gate RG. When the reset transistor RX is turned on by the reset signal, a predetermined electrical potential, for example, a power source voltage VDD, provided to the drain of the reset transistor RX may be transmitted to the floating diffusion region FD.

FIG. 2 shows that the photoelectric conversion layer PD electrically shares one floating diffusion region FD, which is a nonlimiting example. One unit pixel region may include at least one of the photoelectric conversion layers, and the floating diffusion region FD, and the transmission, source follower, selection, and reset transistors, and the reset transistor RX, the source follower transistor SX, or the selection transistor may be shared by the neighboring unit pixel regions.

In an embodiment, as the area of the unit pixel region is reduced, the photoelectric conversion layer PD and the transmission transistor TX may be formed on one semiconductor chip, and the reset transistor, the source follower transistor, and the selection transistor may be formed on another semiconductor chip. The semiconductor chips may be arranged to form a unit pixel region.

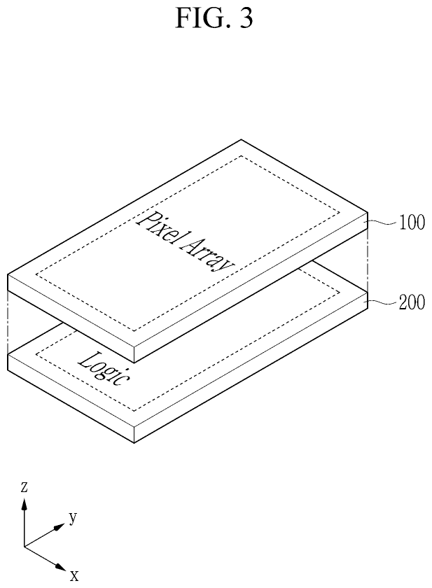

FIG. 3 shows a conceptual layout of an image sensor according to an embodiment of the present disclosure.

Referring to FIG. 3, the image sensor may include a first substrate structure 100 and a second substrate structure 200 that are stacked. The unit pixels may be arranged in a two-dimensional array structure on a plane including an X-axis direction and a Y-axis direction in the first substrate structure 100. As an example, the first substrate structure 100 may include a pixel array, and as such, the pixel array 100 may be interchangeably referred to herein as the first substrate structure 100. The X-axis direction may be perpendicular to the Y-axis direction.

The second substrate structure 200 may include a structure, such as a logic region (e.g., the logic circuit 200 in FIG. 3), and as such, the logic circuit 200 may be interchangeably referred to herein as the second substrate structure 200. The second substrate structure 200 may be disposed below the first substrate structure 100. The first substrate structure 100 may be electrically connected to the second substrate structure 200. The second substrate structure 200 may transmit the pixel signal provided from the first substrate structure 100 to the logic region of the second substrate structure 200.

The second substrate structure 200 may include a same member as the logic region. The second substrate structure 200 may be disposed below the first substrate structure 100. The first substrate structure 100 may be electrically connected to the second substrate structure 200. The second substrate structure 200 may transmit the pixel signal provided from the first substrate structure 100 to the logic region of the second substrate structure 200.

Logic devices may be disposed in the logic region of the second substrate structure 200. The logic devices may include circuits for processing pixel signals received from the unit pixels.

The first substrate structure 100 and the second substrate structure 200 may be stacked in a Z-axis direction. The Z-axis direction may be perpendicular to the X-axis direction and the Y-axis direction.

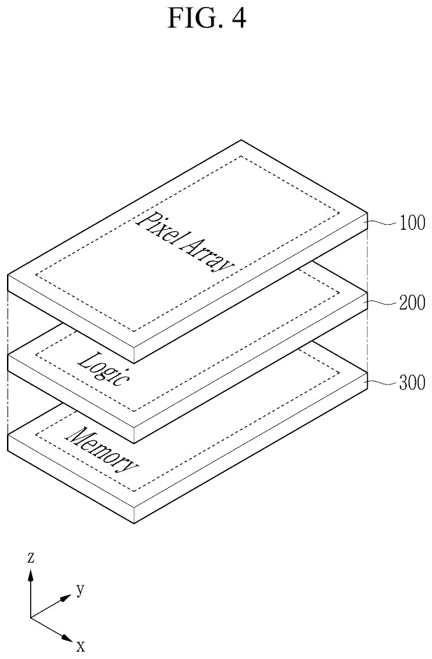

FIG. 4 shows a conceptual layout of an image sensor according to another embodiment of the present disclosure.

Referring to FIG. 4, the image sensor may further include a third substrate structure 300. The first substrate structure 100, the second substrate structure 200, and the third substrate structure 300 may be sequentially stacked in the Z-axis direction. The third substrate structure 300 may be disposed below the second substrate structure 200. As an example, the second substrate structure 200 may be disposed between the first substrate structure 100 and the third substrate structure 300.

The third substrate structure 300 may include a memory device. The third substrate structure 300 may, for example, include a volatile memory device such as a DRAM or an SRAM. The third substrate structure 300 may receive signals from the first substrate structure 100 and the second substrate structure 200 and may process the signals through the memory device.

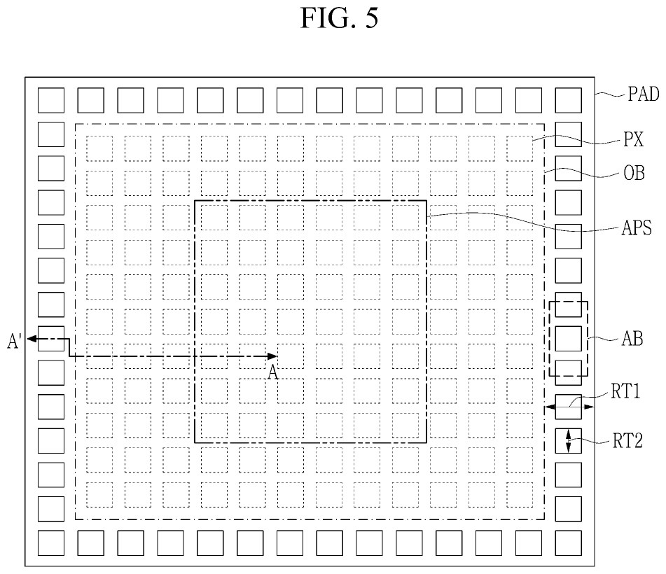

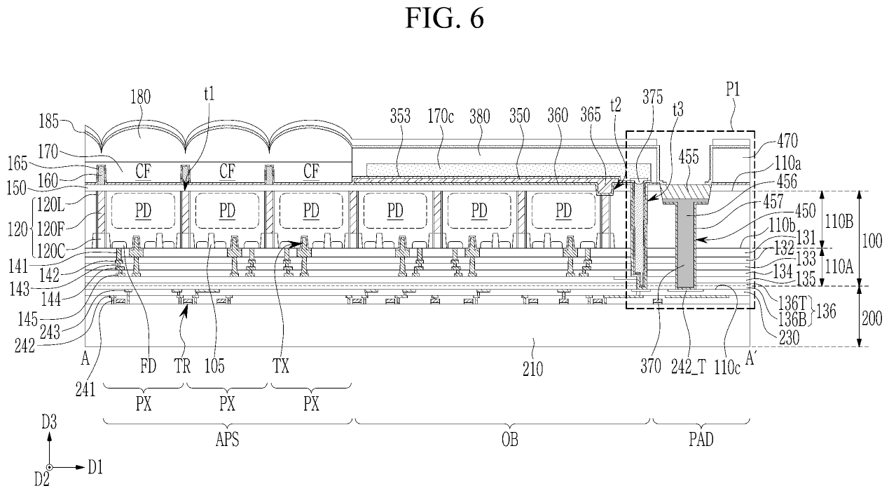

FIG. 5 shows a layout diagram of an image sensor according to an embodiment of the present disclosure. FIG. 6 shows a cross-sectional view with respect to a line A′-A of FIG. 5.

Referring to FIG. 5 and FIG. 6, the image sensor may include a first substrate structure 100 and a second substrate structure 200. The first substrate structure 100 and the second substrate structure 200 may respectively be a sensor chip and a logic chip.

The first substrate structure 100 may include a light receiving region APS, a light blocking region OB, and a pad region PAD. Unit pixel regions PX arranged in two-dimensional way, for example, a matrix may be formed in the light receiving region APS and the light blocking region OB. The unit pixel region PXs may be arranged in a matrix on a plane on which the first direction D1 and the second direction D2 extend. The first direction D1 may intersect the second direction D2. The first direction D1 may be substantially perpendicular to the second direction D2. A third direction D3 may be substantially perpendicular to the first direction D1 and the second direction D2.

Active pixels for receiving light and generating active signals may be arranged in the light receiving region APS. Optical black pixels for blocking light and generating optical black signals may be arranged in the light blocking region OB. The light blocking region OB may be formed around/to at least partially surround the light receiving region APS as a nonlimiting example.

In an embodiment, dummy unit pixel regions may be formed in the light blocking region OB. The dummy unit pixel region may be a pixel generating no active signal.

The pad region PAD may be formed around/to at least partially surround the light blocking region OB. The pad region PAD may be formed near an edge of the image sensor as a nonlimiting example. The pad region PAD may be connected to a member, such as an external device, and may be configured to transmit and receive electrical signals between the image sensor and the external device. As an example, a second pad pattern may be connected to the member, such as the external device on an upper substrate 110B of the pad region PAD.

In an embodiment, the image sensor may include a first substrate structure 100 including an upper substrate 110B and a lower substrate 110A, a pixel separating pattern 120, a surface insulation layer 150, a first color filter 170, a grid pattern 160, a micro lens 180, and a second substrate structure 200 disposed below the first substrate structure 100 and including a second substrate 210.

The upper substrate 110B may be a semiconductor substrate. As an example, the upper substrate 110B may be bulk silicon or a silicon-on-insulator (SOI). The upper substrate 110B may be a silicon substrate. The upper substrate 110B may, for example, be made of a material including silicon, silicon germanium, an indium antimonide, a lead telluride compound, an indium arsenide, an indium phosphide, a gallium arsenide, or a gallium antimonide. In an embodiment, the upper substrate 110B may be an epitaxial layer formed on a base substrate.

The upper substrate 110B may include a first side 110_1 and a second side 110_2 facing each other. In an embodiment, the first side 110_1 of the upper substrate 110B may be a light receiving side. In an embodiment, the image sensor may be a back side illumination (BSI) image sensor.

Unit pixel regions PX may be formed in the upper substrate 110B of the light receiving region APS and the light blocking region OB. The respective unit pixel regions PX may include a photoelectric conversion layer PD. In an embodiment, the dummy unit pixel region including no photoelectric conversion layer PD may be further included in the upper substrate 110B of the light blocking region OB, but is not limited thereto. The signal generated by the dummy unit pixel region may be used as information for removing processing noise.

The respective unit pixel regions PX may include a photoelectric conversion layer PD, a floating diffusion region FD, and a transmission transistor TX. The photoelectric conversion layer PD may be formed in the upper substrate 110B of the light receiving region APS and the light blocking region OB. The photoelectric conversion layer PD may generate charges in proportion to the amount of light input from the outside/external environment. The photoelectric conversion layer PD may transmit the generated and stored charges to the floating diffusion region FD.

The floating diffusion region FD may be formed in the upper substrate 110B of the light receiving region APS and the light blocking region OB. The floating diffusion region FD may be formed in the second side 110_2 of the upper substrate 110B. The charges transmitted to the floating diffusion region FD may be applied to the source follower gate SF of FIG. 2.

The transmission transistor TX may be in the upper substrate 110B. A first end of the transmission transistor TX may be connected to the photoelectric conversion layer PD, and a second end of the transmission transistor TX may be connected to the floating diffusion region FD. The transmission transistor TX may transmit the charges generated by the photoelectric conversion layer PD to the floating diffusion region FD.

The transmission transistor TX may include a transmission gate, a gate insulating layer, and a gate spacer. The transmission gate may include a portion in the upper substrate 110B. The gate insulating layer may be disposed between the transmission gate and the upper substrate 110B. The gate spacer may be disposed on both sidewalls of the transmission gate.

The pixel separating pattern 120 may be formed in the upper substrate 110B. The pixel separating pattern 120 may be formed when a conducting material is in a deep trench formed by patterning the upper substrate 110B, and may be insulated when a liner layer that is an insulating material is formed between the conducting material and the upper substrate 110B.

The pixel separating pattern 120 may extend into the upper substrate 110B in a third direction D3. As an example, the pixel separating pattern 120 may extend to the first side 110a from the second side 110b. As a specific example, the pixel separating pattern 120 may be a front deep trench isolation (FDTI).

The pixel separating pattern 120 may define unit pixel regions PX. In another embodiment, the pixel separating pattern 120 may define unit pixel regions PX and dummy unit pixels (not shown). The pixel separating pattern 120 may be formed to have a lattice shape in a plan view and may separate the unit pixel regions PX from each other.

The pixel separating pattern 120 may have a lattice structure extending in the first direction D1 and the second direction D2.

In a cross-sectional view, the pixel separating pattern 120 may extend into the upper substrate 110B in the third direction D3. The pixel separating pattern 120 may extend to the first side 110_1 from the second side 110_2 of the upper substrate 110B. The pixel separating pattern 120 may be a deep trench isolation (DTI) film. A width of the pixel separating pattern 120 in the second direction D2 may gradually decrease or may have a same width when approaching the first side 110_1 from the second side 110_2 of the upper substrate 110B. However, the present disclosure is not limited thereto.

The pixel separating pattern 120 may include a liner layer 120L, a pixel separating peeling film 120F, and a capping film 120C. The liner layer 120L may be disposed on a sidewall and a bottom side of the first trench t1. In an embodiment, the bottom side of the first trench t1 represents a side that faces the first side 110_1 of the upper substrate 110B. The pixel separating peeling film 120F may be disposed on the liner layer 120L. The capping film 120C may be disposed on the first pixel separating peeling film 120F.

The liner layer 120L may include an oxide layer with a refractive index that is lower than that of the upper substrate 110B. The liner layer 120L may, as a nonlimiting example, include at least one of a silicon oxide, an aluminum oxide, a tantalum oxide, and combinations thereof.

The liner layer 120L with the refractive index that is lower than that of the upper substrate 110B may refract or reflect light obliquely input to the photoelectric conversion layer PD. The liner layer 120L may prevent photocharges generated in a specific unit pixel region PX by incident light from moving to the adjacent unit pixel region PX according to a random drift. As an example, the liner layer 120L may increase a light receiving rate of the photoelectric conversion layer PD and may improve quality of the image sensor.

The pixel separating peeling film 120F may include an insulating material or a conducting material. The insulating material may include a silicon-based insulating material, such as a silicon nitride, a silicon oxide, or a silicon oxynitride, and a high-dielectric material, such as a hafnium oxide, an aluminum oxide, or a tantalum oxide. In an embodiment, the pixel separating peeling film 120F may be a low-resistance conducting material. As a nonlimiting example, the conducting material may include silicon and may be doped with polysilicon (Poly Si), arsenide (As), phosphorus (P), or carbon (C). In an embodiment, a negative voltage may be applied to the pixel separating peeling film 120F including a conducting material. Accordingly, electrostatic discharge (ESD) bruise defects of the image sensor may be prevented. The ESD bruise defects represent a phenomenon of generating stains, such as images or bruises, when the charges generated by the reaction such as the ESD are stacked on the surface of the substrate, for example, the first side 110_1.

The capping film 120C may include an insulating material. For example, the capping film 120C may include a silicon-based insulating material, such as a silicon nitride, a silicon oxide, or a silicon oxynitride, and a high dielectric material, such as a hafnium oxide or an aluminum oxide. The capping film 120C may, as a nonlimiting example, include the same material as the first capping pattern 375 and the second capping pattern 475.

In an embodiment, a trench isolation pattern 105 may be provided. The trench isolation pattern 105 may be disposed in the upper substrate 110B. For example, the trench isolation pattern 105 may be disposed in the trench from which a portion of the upper substrate 110B is recessed. As an example, the trench may be recessed from the second side 110_1 of the upper substrate 110B. The trench isolation pattern 105 may be a shallow trench isolation (STI) film. The trench isolation pattern 105 may define active regions.

A width of the trench isolation pattern 105 in the first direction D1 or the second direction D2 may gradually decrease when approaching the first side 110_1 from the second side 110_2 of the upper substrate 110B. The trench isolation pattern 105 may overlap the pixel separating pattern 120 in the second direction D2 or the first direction D1. The pixel separating pattern 120 may extend into the trench isolation pattern 105 in the third direction D3. The trench isolation pattern 105 may include an insulating material. The insulating material may, for example, include at least one of a silicon nitride, a silicon oxide, and a silicon oxynitride.

The trench isolation pattern 105 may define the active regions. The active regions may, as a nonlimiting example, have a linear shape extending in the second direction D2 in a plan view. A floating diffusion region FD, a transmission transistor TX, a selection transistor, a reset transistor RX, and a source follower transistor SX may be provided in the active regions. As an example, the transmission transistor TX may include a transmission gate TG.

In an embodiment, the floating diffusion region FD may be provided on one side of the transmission transistor TX. The floating diffusion region FD may have a conductivity that is opposite to the conductivity of the upper substrate 110B. For example, the floating diffusion region FD may be doped with N-type impurities. The floating diffusion region FD may cover or overlap the transmission gate TG of the transmission transistor TX.

In an embodiment, part of the unit pixel region PX may include a selection transistor and a source follower transistor SX. The selection transistor may include a selection gate SEL, and the source follower transistor SX may include a source follower gate SF. Another part of the unit pixel region PX may include a reset transistor RX. The reset transistor RX may include a reset gate RG. However, the present disclosure is not limited thereto, and the arrangement and the number of the transistors included in the unit pixel region PX may vary in other embodiments.

In an embodiment, the image sensor may further include first line insulation layers 131, 132, 133, 134, 135, and 136. The first line insulation layers 131, 132, 133, 134, 135, and 136 may cover or overlap the second side 110_1 of the upper substrate 110B. The upper substrate 110B and the first line insulation layers 131, 132, 133, 134, 135, and 136 may form the first substrate structure 100. The number of layers of the first line insulation layers is not limited to the embodiment illustrated in FIG. 6, and the first line insulation layers 131, 132, 133, 134, 135, and 136 may, for example, may include at least one of a silicon oxide, a silicon nitride, a silicon oxynitride, and a low dielectric constant (Low-k) material with a dielectric constant that is lower than that of the silicon oxide.

In an embodiment, the first line insulation layer 136 connects the upper substrate 110A and the lower substrate 110B, and may further include an upper insulation layer 136T and a lower insulation layer 136B. The upper insulation layer 136T and the lower insulation layer 136B may be made of a same film material, and may be divided by an interface at which the upper substrate 110A and the lower substrate 110B are connected.

First contacts 141 and 143 and first wire patterns 142, 144, and 145 may be provided in the first line insulation layers 131, 132, 133, 134, 135, and 136. The first contacts 141 and 143 may electrically connect the floating diffusion region FD and the first wire patterns 142, 144, and 145. Some of the first wire patterns 142, 144, and 145 may be connected to a first connection structure 360. In other embodiments, the first contacts 141 and 143 may be connected to the first wire patterns 142, 144, and 145 in many forms, and the number/arrangement of the first contacts 141, 143 and the first wire patterns 142, 144, 145 are not limited thereto.

The first contacts 141 and 143 and the first wire patterns 142, 144, and 145 may, as a nonlimiting example, include at least one of tungsten (W), copper (Cu), aluminum (Al), gold (Au), silver (Ag), and alloys thereof.

The second substrate 210 is a constituent element of the second substrate structure 200 disposed below the first substrate structure 100, and it may be bulk silicon or a silicon-on-insulator (SOI). The second substrate 210 may be a silicon substrate. The second substrate 210 may, for example, include silicon germanium, an indium antimonide, a lead telluride compound, indium arsenide, indium phosphide, gallium arsenide, or a gallium antimonide. The second substrate 210 may be an epitaxial layer formed on the base substrate.

Transistors TR may be formed on an upper side of the second substrate 210. The transistor TR may control the transmission transistor TX, the reset transistor RX, the selection transistor, and the source follower transistor SX.

A second line insulation layer 230 may be formed on the second substrate 210. For example, the second line insulation layer 230 may cover or overlap the upper side of the second substrate 210. An upper side of the second line insulation layer 230 may contact the third side 100c that is a lower side of the lower substrate 110A of the first substrate structure 100. The second line insulation layer 230 may, as a nonlimiting example, include at least one of a silicon oxide, a silicon nitride, a silicon oxynitride, and a low dielectric constant (low-k) material with a dielectric constant that is lower than that of the silicon oxide.

A second contact 241 and second wire patterns 242 may be disposed in the second line insulation layer 230. The second contact 241 may contact the second wire patterns 242, the second wire patterns 242 may be connected to the transistors TR and may be connected to the floating diffusion region FD of the first substrate structure 100. For example, some of the second wire patterns 242 may be connected to the first connection structure 360. Others of the second wire patterns 242 may be connected to the second connection structure 457.

The second contact 241 and the second wire patterns 242 may, as a nonlimiting example, include at least one of tungsten (W), copper (Cu), aluminum (Al), gold (Au), silver (Ag), and alloys thereof, but are not limited thereto.

The surface insulation layer 150 may be formed on the first side 110_1 of the upper substrate 110B. The surface insulation layer 150 may extend along the second side 110_2 of the upper substrate 110B. In an embodiment, at least part of the surface insulation layer 150 may contact the pixel separating pattern 120. Here, a lower side of the surface insulation layer 150 may contact the pixel separating pattern 120.

The surface insulation layer 150 may include an insulating material. For example, the surface insulation layer 150 may include at least one of a silicon oxide, a silicon nitride, a silicon oxynitride, an aluminum oxide, a hafnium oxide, a titanium oxide, a tantalum oxide, and combinations thereof, but is not limited thereto.

The surface insulation layer 150 may be configured to operate as an anti-reflection film to prevent reflection of light input to the upper substrate 110B, and allows easy inputting of the incident light to increase the light receiving rate of the photoelectric conversion layer PD. Further, the surface insulation layer 150 may function as a planarization layer, and may form the first color filter 170 and the micro lens 180 to have a uniform height without distortion.

The first color filter 170 may be formed on the surface insulation layer 150 of the light receiving region APS. In an embodiment, the first color filter 170 may be formed on the surface insulation layer 150 of the light receiving region APS. In an embodiment, the first color filter 170 may be arranged to correspond to the respective unit pixel regions PX. As an example, the first color filters 170 may be arranged in a two-dimensional manner, for example, in a matrix form.

The first color filter 170 may have various color filters according to the unit pixel region PX. For example, the first color filter 170 may be arranged as a Bayer pattern including a red color filter, a green color filter, and a blue color filter. This is a nonlimiting example, and the first color filter 170 may include a yellow filter, a magenta filter, and a cyan filter, and may further include a white filter.

The grid pattern 160 may be formed on the surface insulation layer 150. The grid pattern 160 may be formed to have a lattice shape on a plane and may be provided among the first color filters 170. The grid pattern 160 may increase a quality of the image sensor by refracting or reflecting light obliquely input to the image sensor.

The grid pattern 160 may include a metallic material for reflecting light or a material with a low refractive index that is lower than the refractive index of silicon (Si). For example, the grid pattern 160 may include at least one of a tungsten metal, an aluminum metal, a titanium metal, a titanium nitride metal, a silicon oxide, a silicon oxide having collected an air layer, a polymer material with a low refractive index, and combinations thereof.

In an embodiment, a first protective layer 165 may be formed on the surface insulation layer 150 and the grid pattern 160. The first protective layer 165 may be provided between the surface insulation layer 150 and the first color filter 170 and between the grid pattern 160 and the first color filter 170. For example, the first protective layer 165 may prevent the surface insulation layer 150 and the grid pattern 160 from being damaged.

The micro lens 180 may be formed on the first color filter 170. The micro lens 180 may be arranged to correspond to the respective unit pixel regions PX. The micro lens 180 may be arranged in a two-dimensional manner, for example, in a matrix form in a plan view.

The micro lens 180 may have a convex shape, and may have a curvature radius within a predetermined range. With the curvature radius within the predetermined range, the micro lens 180 may condense light input to the photoelectric conversion layer PD. For example, the micro lens 180 may, as a nonlimiting example, include a light transmitting resin.

In an embodiment, a second protective layer 185 may be formed on the micro lens 180. The second protective layer 185 may extend along a surface of the micro lens 180. The second protective layer 185 may, for example, include an inorganic oxide layer. The second protective layer 185 may, as a nonlimiting example, include at least one of a silicon oxide, a titanium oxide, a zirconium oxide, a hafnium oxide, and combinations thereof. In an embodiment, the second protective layer 185 may, for example, include a low temperature oxide (LTO).

The second protective layer 185 may protect the micro lens 180 from the outside/external environment. For example, as the second protective layer 185 includes an inorganic oxide layer, it may protect the micro lens 180 including an organic material. Further, the second protective layer 185 may increase light condensing performance of the micro lens 180. For example, the second protective layer 185 may be in the space among the micro lenses 180 to thus reduce reactions, such as reflection, refraction, or scattering of incident light reaching the space among the micro lenses 180.

In an embodiment, the image sensor may further include a first connection structure 360. The first connection structure 360 may be formed in the light blocking region OB. The first connection structure 360 may be disposed in the light blocking region OB and may block the light input to the light blocking region OB. The first connection structure 360 may be formed on the surface insulation layer 150 of the light blocking region OB. The first connection structure 360 may contact the pixel separating pattern 120.

A second trench t2 for exposing the pixel separating pattern 120 may be formed in the upper substrate 110B and the surface insulation layer 150 of the light blocking region OB. The first connection structure 360 may be formed in the second trench t2 and may contact the pixel separating pattern 120 in the light blocking region OB. The first connection structure 360 may extend along a profile of the sidewall and the bottom side of the second trench t2.

The first connection structure 360 may be electrically connected to the pixel separating pattern 120. For example, the first connection structure 360 may be connected to the conductive layer of the pixel separating pattern 120. The first connection structure may, as a nonlimiting example, include a titanium (Ti) film, a titanium nitride (TiN) film, and a tungsten (W) film that are sequentially stacked.

In an embodiment, a first pad pattern 365 may be formed on the first connection structure 360. The first pad pattern 365 is made of a metallic material for blocking light around the pixel array, and it may be in the portion of the second trench t2. A first voltage may be applied to the pixel separating pattern 120 through the first pad pattern 365. For example, a negative voltage may be applied to the conductive layer through the first pad pattern 365 and first connection structure 360 including a conducting material, and hence, the charges generated by the reaction, such as the ESD, may be discharged to the first pad pattern 365 through the pixel separating pattern 120, and the ESD bruise defects may be prevented.

The first pad pattern 365 may, as a nonlimiting example, include at least one of tungsten (W), copper (Cu), aluminum (AI), gold (Au), silver (Ag), and alloys thereof.

In an embodiment, a third trench t3 may be formed in the upper substrate 110B of the light blocking region OB. The third trench t3 may expose a portion of the first wire pattern 145 of the first substrate structure 100. For example, the third trench t3 may represent a through silicon via.

The third trench t3 may expose a portion of a second wire pattern 243 and a third wire pattern 242 of the second substrate structure 200. The first connection structure 360 may be formed in the third trench t3 and may connect the second wire pattern 243 and the third wire pattern 242. The first connection structure 360 may extend along a sidewall and a bottom side of the third trench t3.

In an embodiment, a first peeling insulation layer 370 may be formed in the first connection structure 360. The first peeling insulation layer 370 may, as a nonlimiting example, include at least one of a silicon oxide, an aluminum oxide, a tantalum oxide, and combinations thereof.

In an embodiment, a first capping pattern 375 may be formed on the first peeling insulation layer 370. The first capping pattern 375 may include a silicon-based insulating material, such as a silicon nitride, a silicon oxide, and a silicon oxynitride, and a high dielectric material such as a hafnium oxide and an aluminum oxide. The first capping pattern 375 may include the same material as the capping film 120C, but is not limited thereto.

In an embodiment, a second color filter 170C may be formed on the first connection structure 360. The second color filter 170C may cover or overlap a portion of the first protective layer 165 of the light blocking region OB. The second color filter 170C may, as a nonlimiting example, include a blue color filter.

In an embodiment, a third protective layer 380 may be formed on the second color filter 170C. For example, the third protective layer 380 may cover or overlap a portion of the first protective layer 165 in the light blocking region OB. In an embodiment, the second protective layer 185 may extend along a surface of the third protective layer 380. The third protective layer 380 may include a light transmitting resin, as a nonlimiting example. In an embodiment, the third protective layer 380 may include the same material as the micro lens 180.

In an embodiment, a penetrating structure 450 that extends into at least a portion of a substrate structure including a first substrate structure 100 and a second substrate structure 200 may be disposed in the pad region PAD. The penetrating structure 450 may form a trench shape, for example, a fourth trench t4, and may extend into at least a portion of the substrate structure. As an example, the penetrating structure 450 may extend into at least a portion of the first substrate structure 100, may extend into the first substrate structure 100, and may extend into at least a portion of the second substrate structure 200. The penetrating structure 450 may, for example, be a back via stack (BVS).

In an embodiment, the second connection structure 457 may be formed in the pad region PAD. The second connection structure 457 may be formed on the surface insulation layer 150 of the pad region PAD. The second connection structure 450 may, as a nonlimiting example, include a titanium (Ti) film, a titanium nitride (TiN) film, or a tungsten (W) film that are stacked.

In an embodiment, a first conductive material layer 455 may be disposed in the second connection structure 457. The first conductive material layer 455 may, as a nonlimiting example, include at least one of tungsten (W), copper (Cu), aluminum (Al), gold (Au), silver (Ag), and alloys thereof.

In an embodiment, a portion of the first conductive material layer 455 may be exposed. For example, an opening for exposing the first conductive material layer 455 may be formed in an upper portion. Hence, the first conductive material layer 455 may be configured to be connected to a member, such as an external device, and transmit/receive electrical signals between the image sensor and the external device.

In an embodiment, at least a predetermined region of the first conductive material layer 455 may be in the upper substrate 110B. As part or all of the first conductive material layer 455 is in the upper substrate 110B, a thickness of the image sensor in the third direction D3 may be minimized, and generation of steps may be minimized.

In an embodiment, the second conductive material layer 456 may be in the penetrating structure 450. The second conductive material layer 456 may be disposed below the first conductive material layer 455 and may contact the first conductive material layer 455. A second conductive material layer 456 may be disposed below the first conductive material layer 455. As an example, the second conductive material layer 456 may be disposed below the first conductive material layer 455 to contact the first conductive material layer 455. The second conductive material layer 456 may, as a nonlimiting example, be at least one of tungsten (W), copper (Cu), aluminum (Al), gold (Au), silver (Ag), and alloys thereof. As the second conductive material layer 456 is disposed below the first conductive material layers 455, the problem of being separately disposed in a region adjacent to the first conductive material layer 455 to absorb tungsten and stains may be solved. As the second conductive material layer 456 is disposed below the first conductive material layer 455, the structure of the image sensor may be simplified.

In an embodiment, a ratio of a long axis RT1 to a short axis RT2 may be 0.8 to 1.7 in a plan view of the pad region PAD. As an example, the ratio may be 0.9 to 1.5. The long axis RT1 may represent a length in an outermost side direction from a center of the image sensor in the pad region PAD, and the short axis RT2 may represent a length of the shortest side of the first conductive material layer 455.

The ratio may be satisfied by disposing the back via stack (BVS) separately disposed in the pad region PAD below the first conductive material layer 455. As the ratio is satisfied, an area of the pad region PAD may be reduced, and a chip size may be reduced.

In an embodiment, the length of the long axis RT1 may be 90 to 150 μm. As an example, the length of the long axis RT1 may be 95 to 125 μm. The length of the short axis RT2 may be 50 to 120 μm. As an example, the length of the short axis RT2 may be 70 to 100 μm.

In an embodiment, a fourth protective layer 470 may be formed on a second connection structure 457 of the pad region PAD. For example, the fourth protective layer 470 may cover or overlap a portion of the first protective layer 165 in the pad region PAD. In an embodiment, the second protective layer 185 may extend along the surface of the fourth protective layer 470. The fourth protective layer 470 may include a light transmitting resin as a nonlimiting example, and the fourth protective layer 470 may have the same material as the micro lens 180. FIG. 6 shows that the pad region PAD is disposed on four sides, which is a nonlimiting example, and in other embodiments, it may be disposed on two or three sides.

In an embodiment, the image sensor may further include a third connection structure (not shown). The third connection structure may be further included in the light blocking region OB. The third connection structure may be formed in the light blocking region OB and may block the incident light. The third connection structure may be formed on the surface insulation layer 150 of the light blocking region OB.

The third connection structure may contact at least a portion of the pixel separating pattern 120. The third connection structure may contact at least a portion of the conductive layer of the pixel separating pattern 120. The third connection structure may refer to the first connection structure 360 in a compossible range.

In an embodiment, a fifth trench (not shown) that exposes the pixel separating pattern 120 may be formed in the upper substrate 110B and the surface insulation layer 150 of the light blocking region OB. The third connection structure may be formed in the fifth trench and may contact at least a portion of the pixel separating pattern 120 in the light blocking region OB. The third connection structure may extend along a profile of a sidewall and a bottom side of the fifth trench.

The third connection structure may be electrically connected to the pixel separating pattern 120. As an example, the third connection structure may include a titanium (Ti) film, a titanium nitride (TiN) film, and a tungsten (W) film that are sequentially stacked.

In an embodiment, an additional pad pattern (not shown) may be formed in the third connection structure. The additional pad pattern may be in the third connection structure and may be in the remaining fifth trench. A voltage may be applied to the pixel separating pattern 120 through the additional pad pattern and the third connection structure including a conducting material. For example, the voltage may be a well bias voltage.

The additional pad pattern may include at least one of tungsten (W), copper (Cu), aluminum (Al), gold (Au), silver (Ag), and alloys thereof as a nonlimiting example.

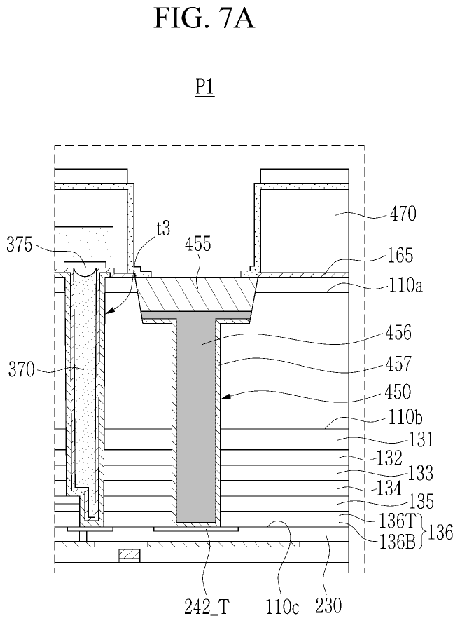

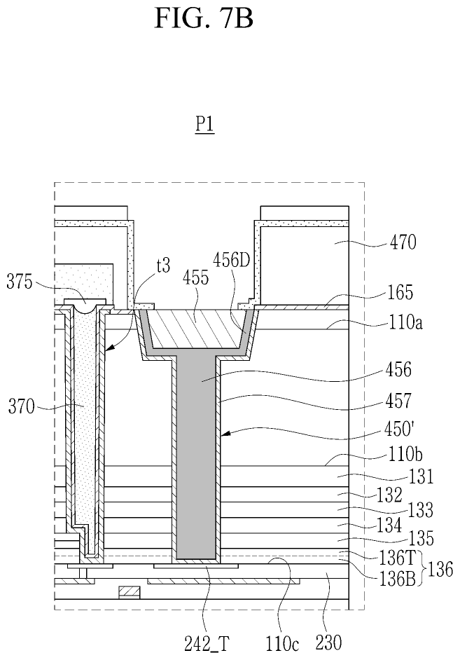

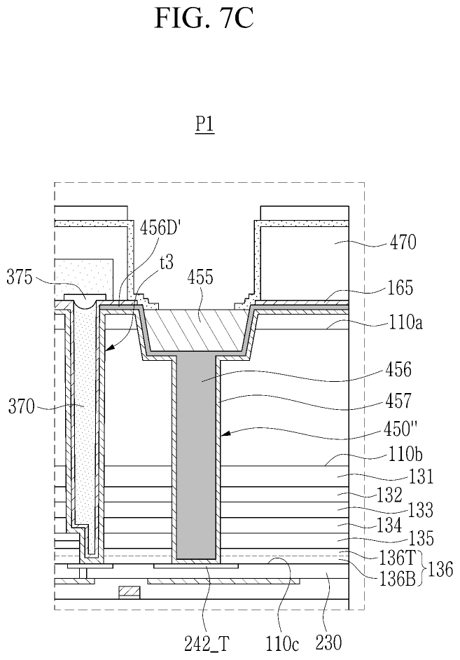

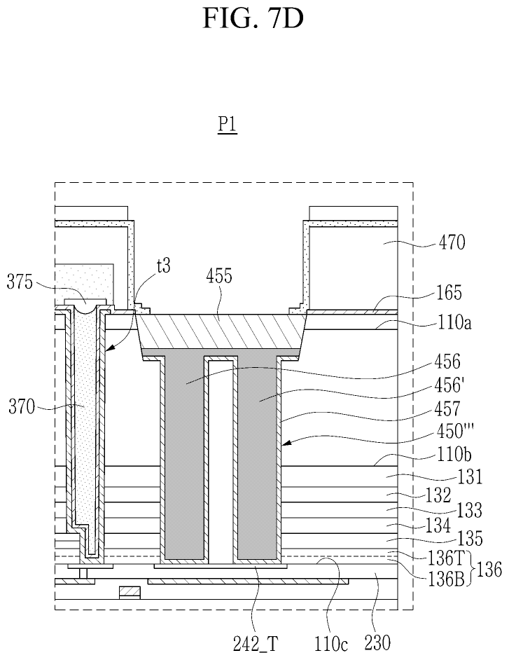

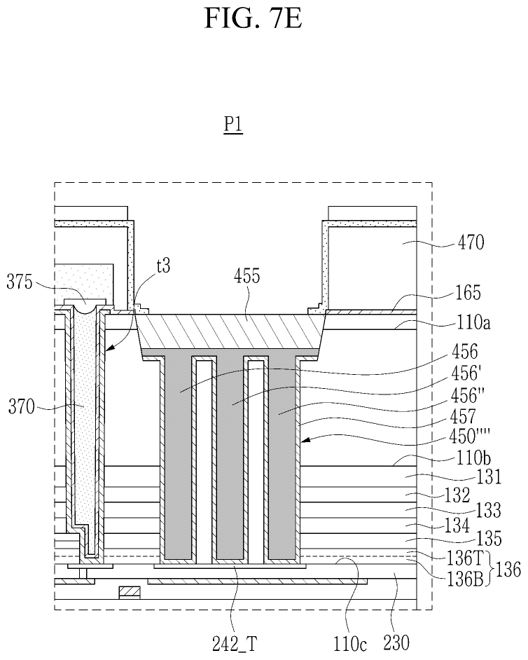

FIG. 7A to FIG. 7E show an enlarged region P1 of FIG. 6 according to various embodiments.

Referring to FIG. 7A, in an embodiment, the pad region PAD of the image sensor may include a penetrating structure 450 including a first conductive material layer 455 disposed in at least a portion of the substrate structure, a second conductive material layer 456 disposed below the first conductive material layer 455, and a second connection structure 457. The second conductive material layer 456 may be disposed below the first conductive material layer 455 to contact the first conductive material layer 455, and may be disposed to extend into at least a portion of the first substrate structure 100 of the substrate structure. As an example, the penetrating structure 450 may extend into an upper substrate 110B configuring the first substrate structure 100 and a lower substrate 110A disposed below the upper substrate 110B.

The second connection structure 457 of the penetrating structure 450 may be connected to second wire patterns 242. As an example, a metal line pattern 242_T connected to the second substrate structure 200 from among the second wire patterns 242 may be connected to the second connection structure 457. As the second connection structure 457 is connected to the metal line pattern 242_T, the first substrate structure 100 may be electrically connected to the second substrate structure 200, the structure may be simplified, and the image sensor may be provided by reducing the use of the metal layer. In an embodiment, the second conductive material layer 456 of the penetrating structure 450 may be disposed below the first conductive material layer 455. As the second conductive material layer 456 is below the first conductive material layer 455, the exposure of the second conductive material layer 456 may be completely removed from the pad region PAD, thereby removing the step of the second conductive material layer 456.

The second connection structure 457 is etched together when the second conductive material layer 456 is etched so the second connection structure 457 may be below the second conductive material layer 456. FIG. 7A shows that the second connection structure 457 is below the second conductive material layer 456, and a portion thereof may be disposed on the sidewall of the second conductive material layer 456 in the etching process.

Referring to FIG. 7B, in an embodiment, the second conductive material layer 456 of the penetrating structure 450′ may surround the sidewall of the first conductive material layer 455. As an example, the second conductive material layer 456 may surround a lower portion of the first conductive material layer 455 and may surround at least a portion of the sidewall of the first conductive material layer 455.

As an example, the second conductive material layer 456 may further include a first dummy conductive material layer 456D. FIG. 7B shows that the first dummy conductive material layer 456D completely surrounds the sidewall of the first conductive material layer 455, which is a nonlimiting example, it should be understood that the first dummy conductive material layer 456D may partially surround at least a predetermined region with respect to a height of the sidewall. As the second conductive material layer 456 surrounds the sidewall of the first conductive material layer 455, exposure of the conductive material may be minimized and the step of the second conductive material layer 456 may be removed.

Referring to FIG. 7C, in an embodiment, the second conductive material layer 456 of the penetrating structure 450″ may include a second dummy conductive material layer 456D′ disposed below the first conductive material layer 455 and extending to the sidewall of the first conductive material layer 455 and at least a predetermined region between the first protective layer 165 and the second connection structure 457.

As an example, the first protective layer 165 may be disposed on the surface insulation layer 150, the connection structure 457 is disposed on the first protective layer 165, and the second conductive material layer may extend to at least a predetermined region between the first protective layer 165 and the connection structure 457.

As a specific example, as the second conductive material layer 456 and the second dummy conductive material layer 456D′ are disposed, the back via stack that is the second connection structure 457 is disposed below the first conductive material layer 455, thereby reducing the defects that are generated when the second connection structure 457 is separately disposed.

Referring to FIG. 7D and FIG. 7E, in an embodiment, penetrating structures 450″ and 450″ may be disposed on a plane.

FIG. 7A to FIG. 7C show that the penetrating structures 450′, 450″, and 450′″ are configured as a single side, which is a nonlimiting example, and the penetrating structures 450″ and 450″ may be disposed as a single side, double sides, or multiple sides. As described herein, the penetrating structures 450′, 450″, 450′″, and 450″″ may be realized in various ways according to modification of designs.

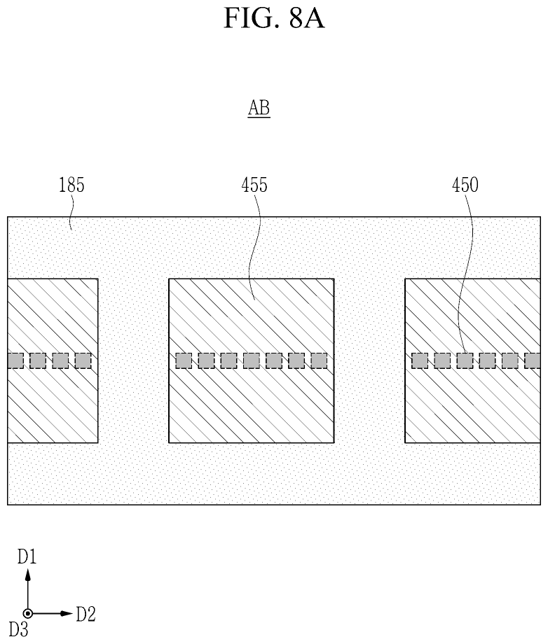

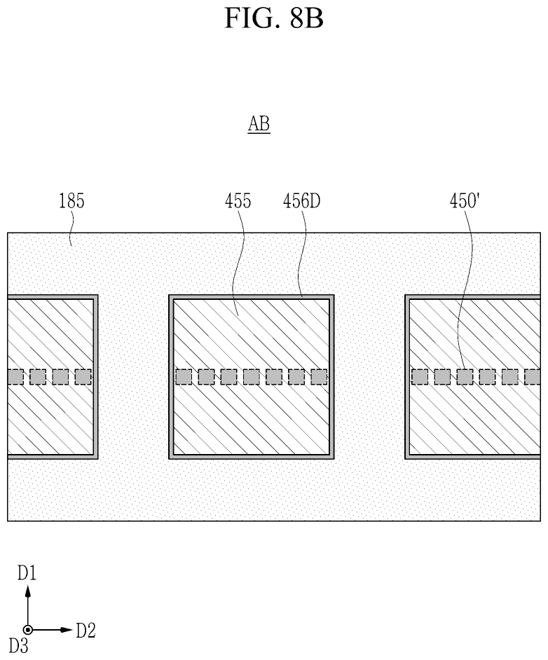

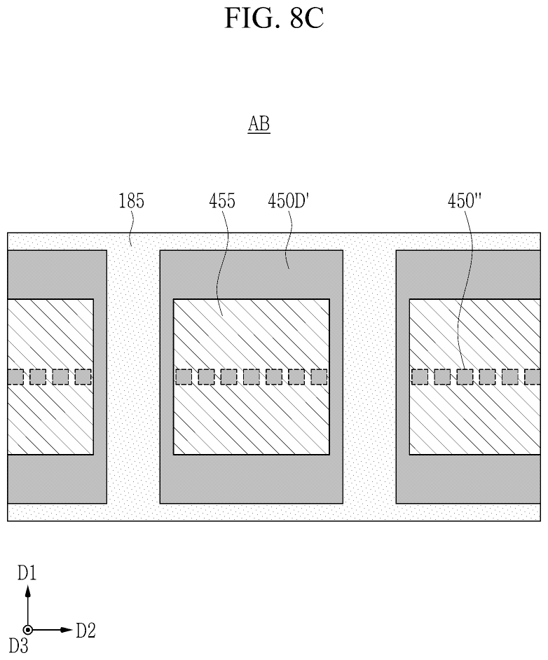

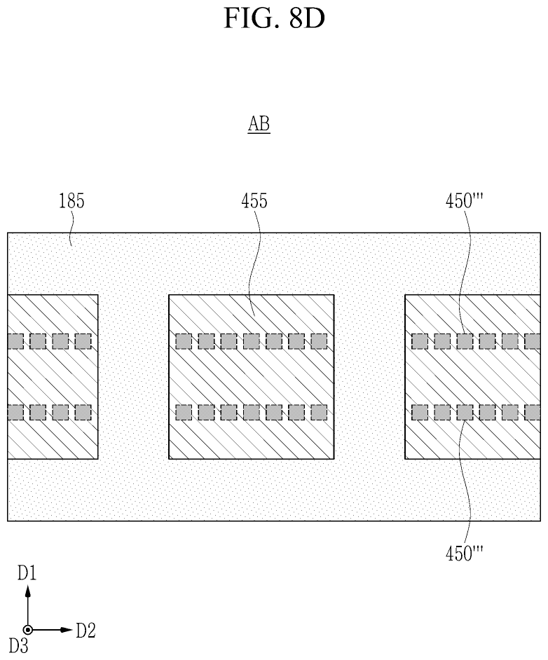

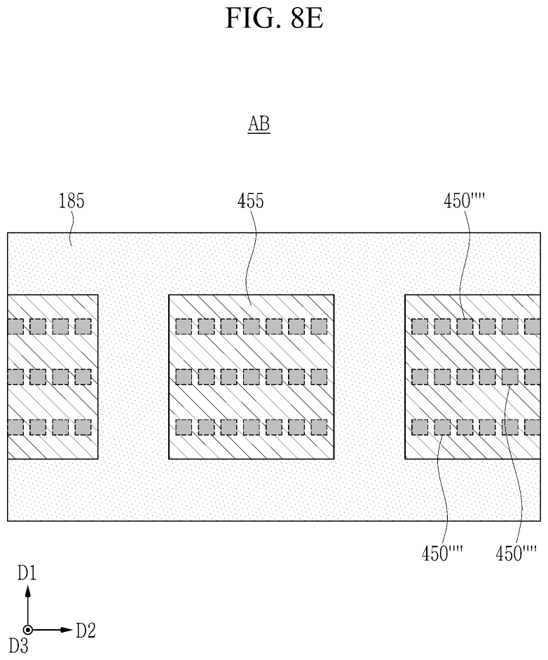

FIG. 8A to FIG. 8E show top plan views of the embodiment described with reference to FIG. 7A to FIG. 7E seen from a region AB of FIG. 6.

Referring to FIG. 7A to FIG. 7E, in an embodiment, the penetrating structures 450, 450′, 450″, 450′″, and 450″″ may be arranged and disposed in the thickness direction of the first conductive material layer 455. The penetrating structures 450, 450′, 450″, 450′″, and 450″″ may be arranged in the first direction D1 of the first conductive material layer 455. The penetrating structures 450, 450′, 450″, 450′″, and 450″″ electrically connect the first substrate structure 100 and the second substrate structure 200, and they may be disposed below the first conductive material layer 455.

FIG. 8A to FIG. 8C show that the penetrating structures 450 may be formed as a single side, As an example, one structure, as shown in FIG. 7A to FIG. 7C. The penetrating structures 450, 450′, 450″, 450′″, and 450′″ may be formed as a single side, and may be disposed in a line in the first direction D1.

FIG. 8D and FIG. 8E show that the penetrating structures 450′″, 450″″ are disposed below the first conductive material layer 455 of the penetrating structure 450″, 450″″ when the penetrating structures 450′″, 450″″ are configured as double sides or multiple sides, as shown in FIG. 7D and FIG. 7E. As an example, the first conductive material layers 455 of the penetrating structures 450 may be arranged to be disposed in the thickness direction.

FIG. 8D and FIG. 8E shows that the penetrating structures 450′″, 450″″ are disposed in columns below the first conductive material layer 455, and may be arranged in the thickness direction of the first conductive material layer 455.

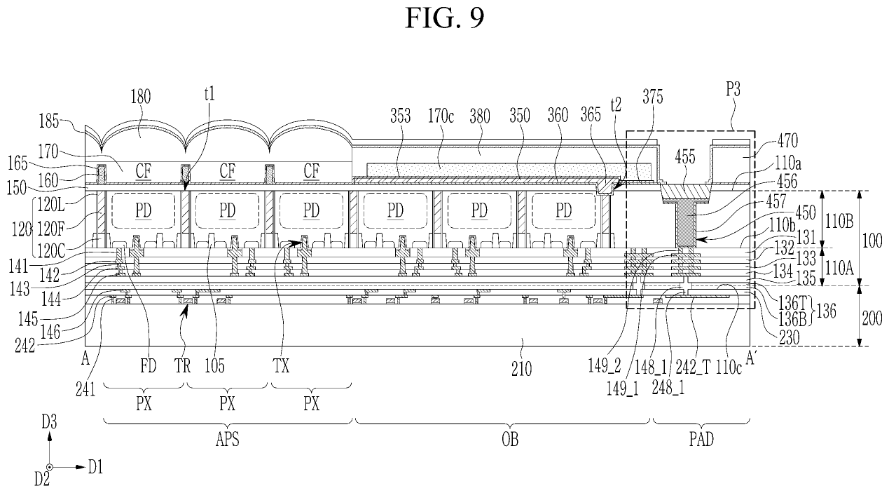

FIG. 9 shows a cross-sectional view of an image sensor with respect to a line AA′ of FIG. 5 according to another embodiment of the present disclosure.

Referring to FIG. 9, the penetrating structures 450′″, 450″″ may extend into at least a portion of the upper substrate 110B, and the penetrating structure 450′″, 450″″ may connect the first substrate structure 100 and the second substrate structure 200 through a wire structure disposed on the lower substrate 110A. The wire structure may include conductive layers 149_1 and vias 149_2. Referring to FIG. 9, the number of layers and the disposition of the conductive layers 149_1 and the vias 149_2 are examples and are not limited thereto.

In an embodiment, the respective conductive layers 149_1 may have a multilayer structure. For example, the conductive layers 149_1 may extend along the plane including the first direction D1 and the second direction D2.

For example, as shown in FIG. 9, the conductive layers 149_1 may be sequentially stacked from the second side 110_2 of the upper substrate 110B and may then be disposed. As an example, the conductive layer 149_1 may be disposed in the lower substrate 110A.

The vias 149_2 may connect the conductive layers 149_1. The vias 149_2 may extend in the third direction D3 and may electrically connect the conductive layers 149_1. The via 149_2 may, for example, have various column shapes, such as a cylinder, a truncated circular cone, a polyprism, or a polygonal pyramid.

The conductive layers 149_1 and the vias 149_2 may include a conducting material. The conducting material may, for example, include at least one of tungsten (W), copper (Cu), aluminum (Al), gold (Au), silver (Ag), and alloys thereof.

A first access pattern 148_1 may be connected to the first wire structure. For example, the first access pattern 148_1 may be connected to a bottom side of the conductive layer 149_1. The first access pattern 148_1 may be exposed from the surface of the first line insulation layer 136. The first access pattern 148_1 may contact the conductive layer that is the most distant/furthest away from the upper substrate 110B.

The first access pattern 148_1 may, for example, have various column shapes such as a cylinder, a truncated circular cone, a polyprism, or a polygonal pyramid. In an embodiment, the first access pattern 148_1 may include a conducting material. The conducting material may include copper (Cu), as a nonlimiting example.

The second access pattern 248_1 may contact the metal line pattern 242_T disposed in the second substrate structure 200. As an example, the second access pattern 248_1 may electrically connect the first access pattern 148_1 and the metal line pattern 242_T. Hence, a wire pattern in the second substrate structure 200 may be electrically connected to the first conductive material layer 455 of the pad region PAD and may transmit/receive electrical signals between the image sensor and the external device.

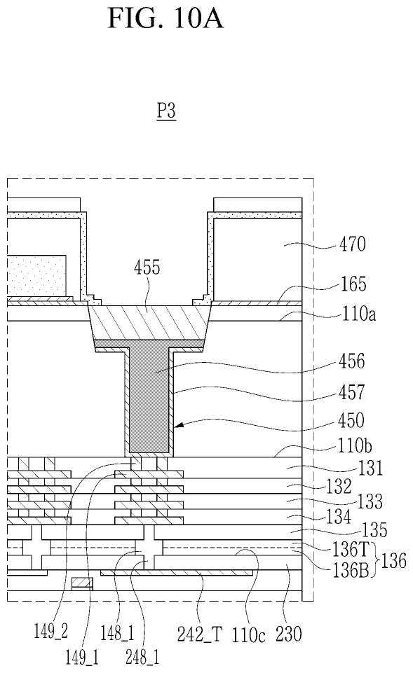

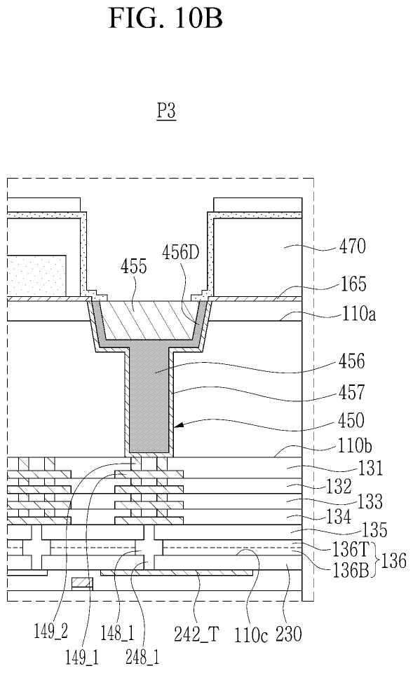

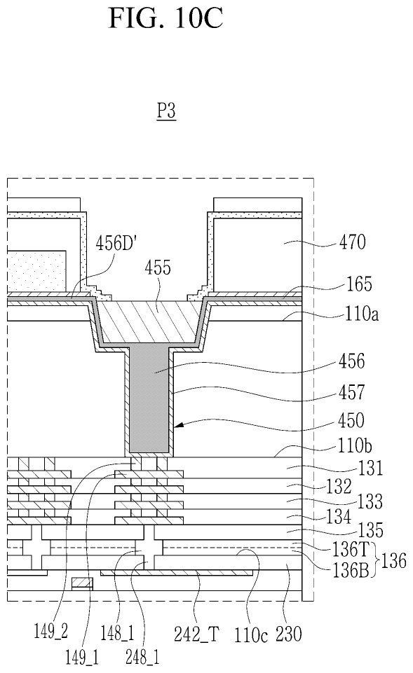

FIG. 10A to FIG. 10C show an enlarged region P3 of FIG. 9.

Referring to FIG. 10A to FIG. 10C, the description given with reference to FIG. 7A to FIG. 7C except that the penetrating structure 450 is connected to the lower substrate 110A of the first substrate structure 100 and the second substrate structure 200 is connected to the first access pattern 148_1 by the second access pattern 248_1. As described, as shown in FIG. 7A to FIG. 7C, the penetrating structure 450 may be connected to the metal line pattern 242_T of the second substrate structure 200, and as shown in FIG. 10A to FIG. 10C, the penetrating structure 450 may be connected to the lower substrate 110A through the wire structures disposed in the second substrate structure 200.

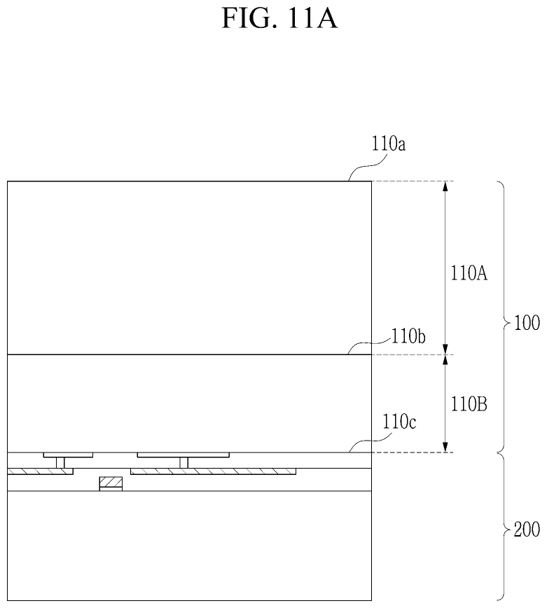

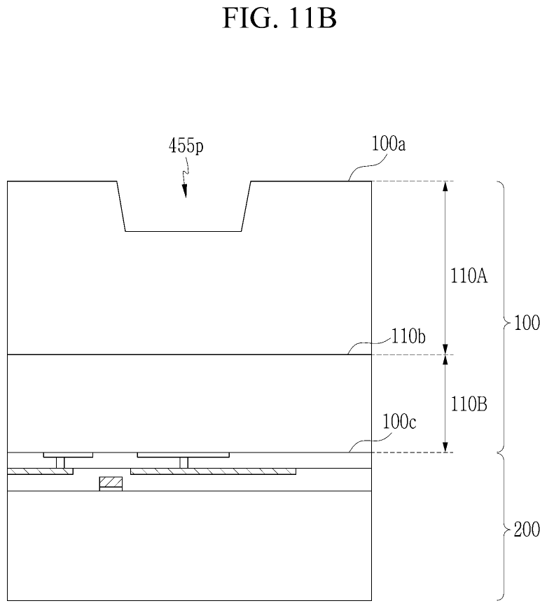

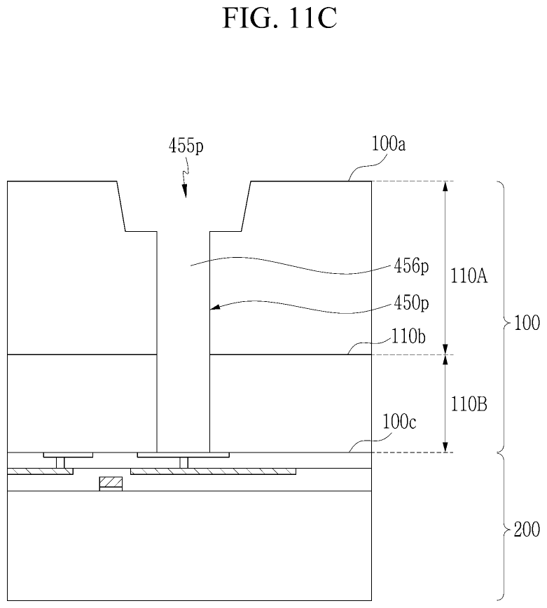

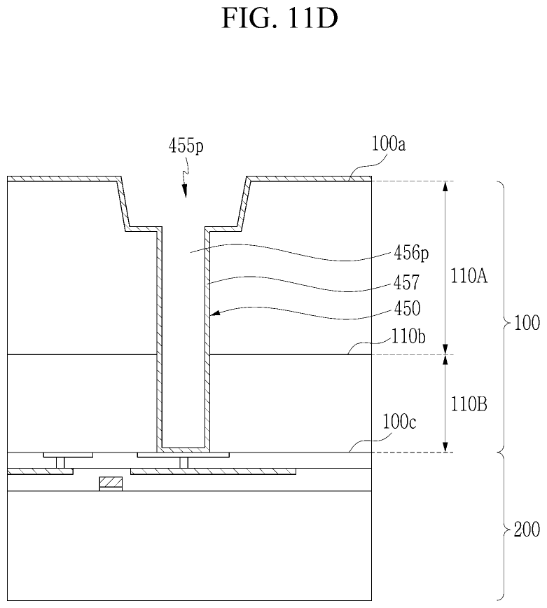

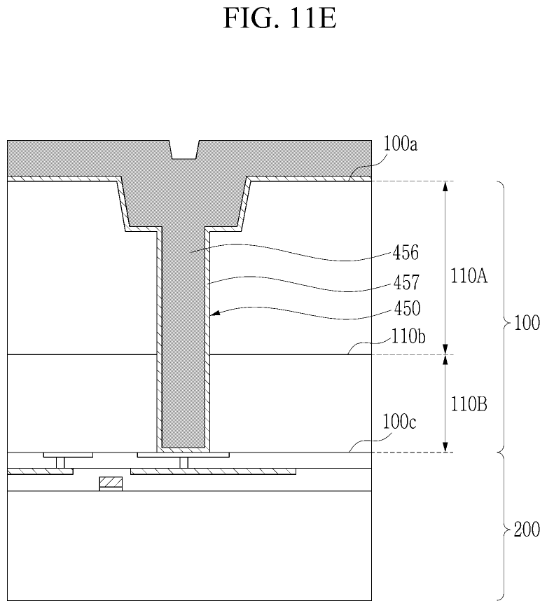

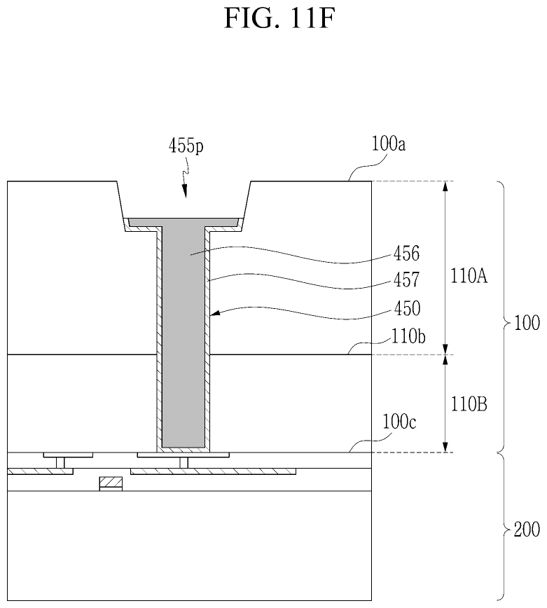

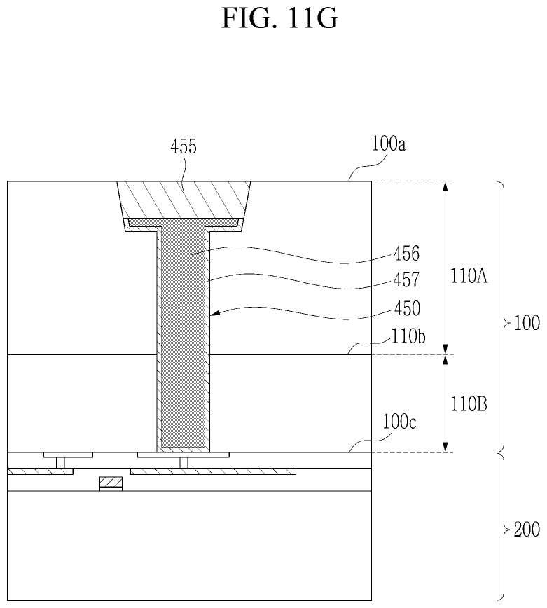

FIG. 11A to FIG. 11G show a method for manufacturing an image sensor according to an embodiment of the present disclosure.

FIG. 11A to FIG. 11G show a method for manufacturing an image sensor according to an embodiment of the present disclosure, and As an example, they show a method for manufacturing an image sensor shown in FIG. 6.

Referring to FIG. 11A, the first substrate structure 100 and the second substrate structure 200 including a lower substrate 110A and an upper substrate 110B may be combined to each other. The first substrate structure 100 may be combined with the second substrate structure 200 according to a static electricity combination of SICN as a nonlimiting example.

Before combining the first substrate structure 100 and the second substrate structure 200 including a lower substrate 110A and an upper substrate 110B, a process for forming a photoelectric converter PD by performing an ion implantation process to the first substrate structure 100 including a light receiving region APS and a light blocking region OB, and a process for manufacturing a pixel separating pattern 120 may be performed. The above-described stages may be performed by conventional processes.

Referring to FIG. 11B, a pad trench 455p may be formed in the first substrate structure 100. The pad trench 455p may be a region in which the first conductive material layer 455. As an example, a conductive pad is formed. The pad trench 455p may be formed by various methods, such as an etching process.

Referring to FIG. 11C, at least one penetration hole 450p may be formed below the pad trench 455p. The penetration hole 450p may be formed by the same or different methods as the pad trench 455p, and may be etched to extend into the first substrate structure 100.

Referring to FIG. 11D, after forming at least one penetration hole 450p below the pad trench 455p, a connection structure 457 may be applied to the pad trench 455p and the penetration hole 450p. As an example, applying a connection structure 457 to the pad trench 455p and the penetration hole 450p may include applying a connection structure 457 on sidewalls of the pad trench 455p and the penetration hole 450p.

In an embodiment, before the forming of a conductive material layer in the penetration hole 450p by using a first conductive material, an adhesive material may be further applied. As an example, the adhesive material may allow the first conductive material and the second conductive material to be easily adhered to the pad trench 455p and the penetration hole 450p. As an example, the adhesive material may, for example, include a titanium (Ti) film or a titanium nitride (TiN) film.

Referring to FIG. 11E, a conductive material layer may be formed in the penetration hole 450p by using a first conductive material. The conductive material layer represent the above-described second conductive material layer 456. The conductive material may, as a nonlimiting example, include at least one of tungsten (W), copper (Cu), aluminum (Al), gold (Au), silver (Ag), and alloys thereof. The first conductive material may cover or overlap the connection structure 457 and may be applied.

Referring to FIG. 11F, a second conductive material layer 456 may be formed by etching the first conductive material and the connection structure 457. Various types of etching methods may be used to etch the first conductive material and the connection structure 457, and the etching may be performed based on a shape shown in FIG. 7A to FIG. 7C. FIG. 11F shows that the connection structure 457 remains on the sidewall of the second conductive material layer 456, which is a nonlimiting example, and as shown in FIG. 7A, the connection structure 457 may be etched so that it may be disposed below the second conductive material layer 456.

Referring to FIG. 11G, a conductive pad may be formed on the conductive material layer by using a second conductive material. The conductive pad may be the above-described first conductive material layer 455, such as the conductive pad.

In an embodiment, the conductive material layer may contact the entire bottom surface of the conductive pad. As an example, FIG. 11F shows that the conductive material is in a portion of the lower region of the first conductive material layer 455, and as the conductive material is used as shown in FIG. 7B or FIG. 7C, a portion of the conductive material may be disposed on the sidewall of the first conductive material layer 455 and in the connection structure 457. A detailed description thereof may refer to what is described with reference to FIG. 7A to FIG. 7E within the compossible range. The image sensor may be manufactured by a conventional process.

While this disclosure has been described in connection with what is presently considered to be practical embodiments, it is to be understood that the disclosure is not limited to the disclosed embodiments and/or the examples, but, on the contrary, is intended to cover various modifications and equivalent arrangements included within the spirit and scope of the appended claims. Therefore, the embodiments and/or the examples described above are only examples and should not be construed as being limitative in any respects.

What is claimed is:

1. An image sensor comprising:
a substrate structure that comprises a sensor array region and a pad region adjacent to the sensor array region, wherein the substrate structure comprises a first substrate structure and a second substrate structure, and wherein the first substrate structure is on the second substrate structure; and
a penetrating structure comprising a first conductive material layer and a second conductive material layer in at least a portion of the first substrate structure,
wherein the second conductive material layer is on and electrically connected to the first conductive material layer, and wherein the second conductive material layer extends into the first substrate structure.

2. The image sensor of claim 1, wherein the second conductive material layer at least partially surrounds a sidewall of the first conductive material layer.

3. The image sensor of claim 2, wherein:
the image sensor further comprises a first protective layer, a surface insulation layer, and a connection structure,
the first protective layer is on the surface insulation layer,
the connection structure is on the first protective layer, and
the second conductive material layer is between the first protective layer and the connection structure.

4. The image sensor of claim 1, wherein:
the first substrate structure comprises a lower substrate and an upper substrate on the lower substrate, and
the penetrating structure extends into the upper substrate.

5. The image sensor of claim 4, wherein the penetrating structure extends into the lower substrate.

6. The image sensor of claim 5, wherein the penetrating structure is electrically connected to a metal line pattern on an uppermost portion of the second substrate structure.

7. The image sensor of claim 4, further comprising
a wire structure on the lower substrate, wherein the wire structure electrically connects the first substrate structure and the second substrate structure.

8. The image sensor of claim 1, wherein the penetrating structure extends in a thickness direction of the first conductive material layer.

9. The image sensor of claim 1, further comprising a plurality of the penetrating structures, wherein the plurality of penetrating structures extend in a thickness direction of the first conductive material layer.

10. The image sensor of claim 1, wherein a ratio of a length of a long axis of the pad region and a length of a short axis of the pad region is about 0.8 to about 1.7.

11. The image sensor of claim 10, wherein the length of the long axis of the pad region is about 90 to about 150 μm.

12. The image sensor of claim 1, wherein:
the first substrate structure comprises a lower substrate and an upper substrate on the lower substrate, and
at least a portion of the first conductive material layer is in the upper substrate.

13. The image sensor of claim 1, wherein the second conductive material layer comprises at least one of tungsten, copper, aluminum, gold, silver, and alloys thereof.

14. An image sensor comprising:
a substrate structure that comprises a sensor array region and a pad region adjacent to the sensor array region, wherein the substrate structure comprises a first substrate structure and a second substrate structure, wherein the first substrate structure is on the second substrate structure, wherein the first substrate structure comprises an upper substrate and a lower substrate, and wherein the second substrate structure comprises wire patterns; and
a penetrating structure that extends into the first substrate structure,
wherein the penetrating structure comprises a first conductive material layer in at least a portion of the first substrate structure in the pad region, wherein the penetrating structure comprises a second conductive material layer that is on the first conductive material layer and extends into the upper substrate and the lower substrate, and wherein the penetrating structure comprises a connection structure that is electrically connected to the wire patterns.

15. The image sensor of claim 14, wherein the second conductive material layer at least partially surrounds a sidewall of the first conductive material layer.

16. The image sensor of claim 15, wherein:
the image sensor further comprises a first protective layer and a surface insulation layer,
the first protective layer is on the surface insulation layer,
the connection structure is on the first protective layer, and
the second conductive material layer is between the first protective layer and the connection structure.

17. The image sensor of claim 14, wherein a ratio of a length of a long axis of the pad region and a length of a short axis of the pad region is 0.8 to 1.7.

18. An image sensor comprising:
a substrate structure that comprises a first substrate structure and a second substrate structure on the first substrate structure; and
a penetrating structure comprising a first conductive material layer and a second conductive material layer that is on and electrically connected to the first conductive material layer,
wherein the first substrate structure comprises a lower substrate and an upper substrate on the lower substrate, and
wherein the second conductive material layer extends into at least one of the lower substrate and the upper substrate and at least partially surrounds a sidewall of the first conductive material layer.

19. The image sensor of claim 18, wherein:
the second substrate structure further comprises wire patterns, and
the penetrating structure comprises a connection structure that is electrically connected to the wire patterns.

20. The image sensor of claim 19, wherein:
the image sensor further comprises a first protective layer and a surface insulation layer,
the first protective layer is on the surface insulation layer,
the connection structure is on the first protective layer, and
the second conductive material layer is between the first protective layer and the connection structure.
